(19) United States
(12) Patent Application Publication
(10) Pub. No.: US 2006/0146980 A1
(43) Pub. Date: Jul. 6, 2006

(54) Apparatus and method for midamble generation

(76) Inventor: Yanmeng Sun, Shanghai (CN)

Correspondence Address: PHILIPS INTELLECTUAL PROPERTY & STANDARDS, P.O. BOX 3001, BRIARCLIFF MANOR, NY, 10510, US

(21) Appl. No.: 10/540,801

(22) PCT Filed: Dec. 22, 2003
(86) PCT No.: PCT/IB03/06224

§ 371 Date: Jan. 20, 2006

(30) Foreign Application Priority Data
Dec. 26, 2002 (CN) 021597839

(51) Int. Cl. G11C 19/00

(52) U.S. Cl. 377/69

(57) ABSTRACT

An architecture for midamble generation in communication system, in this architecture, a set of identical bi-directional Partial Cyclic Shift Registers (PCSRs) are used to shift different segments of basic midamble codes in parallel, and the sum length of all these bi-directional PCSR is equal to the length of final midamble sequence. In the present invention, the basic midamble codes are periodically extended and loaded into these PCSRs as the original codes of a special sequence. Simultaneously, a comparator is used to control the shift direction and the degree of shift steps. When this architecture accomplishes all the shift operation, all the special sequence in these PCSRs is downloaded as final midamble sequence. This architecture has higher device reuse ratio and lower gate resource cost.

### TECHNICAL FIELD

The present invention reaches communication system, especially an architecture for midamble generation in communication system.

### BACKGROUND OF THE INVENTION

In most time-division duplex (TDD) and code-division multi-access(CDMA) communication systems, since there is no continual and specific steering channel inside, channel estimate and accurate synchronous adjusting i.e. puppet noise (PN) tracking are accomplished by processing training codes.

Usually, training sequence such as midamble is a set of sequences of special codes with considerable self-related and co-related features, embedded in the middle of transfer space. For instance, as shown in FIG. 1, in UTRAN TDD low code-piece rate mode of general mobile land-wireless-access electronic communication net i.e. time division and synchronous code division multi-access (TD-SCDMA) system, 144 bits midamble is located between two data segments.

To divide different channels of different users in a same community, each mobile user in that community has own midamble. As said before, all these midambles have considerable co-related features, helping to extract the signal of any user from mixed signals for the system.

Usually, midambles are generated from a fixed codes group pre-defined by system regulations, and delivered to each community during the entire network setting. This fixed codes group is called the basic midamble. In UTRAN TDD(3.84 Mcps and 1.28 Mcps modes), midamble generation is based on Steiner's formula. Midambles of all the users in a community can be reasoned from a basic sequence. Midamble generation is shown in FIG. 2.

As far as each specific basic midamble concerned, its binary form can be expressed by vector mₚ.
mₚ=(m₁,m₂, . . . mₚ) (1)

Parameter p stands for the length of a basic midamble. For example, in UTRAN TDD low code-piece rate mode, p=128.

UTRAN TDD uses Steiner's formula to generate the final midambles. To obtain it, vector mₚ extends periodically to length:
iₘₐₓ=Lₘ+(K−1)·W (2)

Here, Lₘ and K are system parameters (usually, the result of Lₘ minus p is integer times greater than K), and

$$W = p / K \qquad ( 3 )$$

The first p code elements of the new vector m are the same as the p code elements of vector mₚ, and the following code elements repeat the first code elements:

$${\underline{m}}_{i} = \{ \begin{matrix}{\underline{m}}_{i}^{p} & i \leq p \\ {\underline{m}}_{i - p}^{p} & i > p\end{matrix} \qquad ( 4 )$$

Then, according to Steiner's formula, obtain a midamble m^{(k)} of the length of Lₘ from the periodical basic midamble m.
m^{(k)}=(m₁^{(k)},m₂^{(k)}, . . . , m_{L}_{ₘ}^{(k)}) k=1,2, . . . , K (5)

The base on which the code element m₁^{(k)} of the user k's midamble is generated is:
m₁^{(k)=}m_{1+(K-k)W} i=1,2, . . . ,Lₘ k=1,2, . . . ,K (6)

Since the lengths of the basic midamble and the final midamble are not equal (i.e. p≠Lₘ), and different midamble in extended basic midambles has different initial phase, it is inconvenient to use architecture based on traditional Cyclic Shift Register(CSR) to generate all of the midambles (i.e all of the K midambles). One possible way out is to use 2×p latches to load all of the extended basic midambles, and to extract special code segments according to required midamble sum k. For example, as FIG. 2 shows, to obtain the (K−1) midamble, the content of from latch 1+W to latch Lₘ+W should be output.

According to the architecture and system parameters above, 2×p latches must be used. And, for the generation of all the possible midambles (from m⁽¹⁾ to m^{(k)}), large and complicated multiplexers must be used to maintain the output of different segments in latches. Moreover, simple latches are not usually used in code generator of the inner transceiver of the Third Generation (3G) mobile communication system. And since in each time space system needs to generate only one midamble, the reuse ratio of devices is much low. This is very uneconomical to the design of ASIC and embedded platform.

A specific architecture for the generation of midamble will be proposed next. This architecture has higher reuse ratio and lower cost.

### SUMMARY OF THE INVENTION

The present invention is to provide an architecture for the generation of midamble in communication system. Compared to the traditional architecture, this architecture's reuse ratio of resources is higher and cost is much lower.

The present invention is based on bi-directional partial cyclic shift register, which includes a set of data registers serially connected from D₁ to D_{L} which can shift data bi-directionally, wherein L is positive integer greater than 1; two symmetrical partial feedback lines, one is feedback from intermediate data register Dₙ to D₁ to make up of a cycle, the other is feedback from intermediate data register Dₘ to D_{L} to make up of a cycle, wherein m<n (m, n are positive integers greater than 1 respectively); and a direction control input, used to select left/right shift working modes of the bi-directional partial cyclic shift register. When the work mode is selected, only a part of data are in the shift cycle, and rest part of the data will be finally shifted out after a certain number of cycles.

The present invention proposed an architecture for midamble generation in communication system, which includes a set of identical parallel bi-directional partial cyclic shift registers, wherein subscripts of two dimensional matrix are used to identify each data register of bi-directional partial cyclic shift registers, each bi-directional partial cyclic shift register has the same length, and the sum length of all the bi-directional partial cyclic shift registers is equal to the length of final midamble sequence. The direction control inputs of these bi-directional partial cyclic shift registers are connected together, and the left/right shift work modes of all these bi-directional partial cyclic shift registers are controlled by a uniform direction control input signal. The architecture also includes a comparator, the output of which is as the direction control input signal used to define the working modes of these said bi-directional partial cyclic shift registers. All these bi-directional partial cyclic shift registers work absolutely in parallel synchronously and there is no data exchanging or transmitting between each other.

In communication systems, the method of midamble generation with this architecture includes: first, the whole basic midamble sequences are periodically extended and are loaded into all the bi-directional partial cyclic shift registers of the architecture in turn in left-to-right column-prior sequence; after the initial data i.e. extended basic midamble sequence are loaded into the architecture, the comparator compares the number of midamble the system required with an initial constant, and determine the shift direction of all the bi-directional partial cyclic shift registers. All bi-directional partial cyclic shift registers work in right shift mode when the number of the midamble is less than the initial constant, otherwise, all bi-directional partial cyclic shift registers work in left shift mode. And the shift degrees of all the bi-directional partial cyclic shift registers are determined by the shift direction of the bi-directional partial cyclic shift register, the number of the midamble k and an initial constant K; When bi-directional partial cyclic shift register works in right shift mode, the shift degree is K-k otherwise, the shift number is k; According to defined shift direction and degrees, the bi-directional partial cyclic shift registers perform shift operations in parallel in same direction and same degrees; When the architecture has finished the demanded shifting operations, all the data in these bi-directional partial cyclic shift registers are downloaded in turn in left-to-right column-prior sequence, as final midamble sequence.

The positive effect of this invention is: the present invention provides designers higher reuse ratio of devices and lower cost. The main part of this invention is a set of bi-directional partial cyclic shift registers, which combines regular shift registers. Shift registers are broadly used in 3G code generator (such as: channel code, disturbing code, etc.). And in 3G system, midamble sequence and other code sequence (such as: channel code, disturbing code, etc.) don't need as to be generated simultaneously, so designers can easily melt this invention into other code generators and hard devices can be reused in different periods, which improves the reuse ratio of resources. The proposed architecture spares much gate resource. The traditional architecture must use at least 2×p latches to store periodically extended sequence. But this invention only needs Lₘ data registers, usually Lₘ is about a half of 2×p. Since latch consumes as much gate resource as data register does, this invention spares nearly half gate resource.

### BRIEF DESCRIPTION OF THE DRAWINGS

The invention is explained in further detail, and by way of example, with reference to the accompanying drawings wherein:

FIG. 1 shows the structure of time space in UTRAN TDD low code-piece ratio mode;

FIG. 2 shows the generation of UTRAN TDD midambles based on Steiner's formula;

FIG. 3 shows the structure of bi-directional Partial Cyclic Shift Registers in the present invention;

FIG. 4 shows the structure of the present invention's architecture whose generation of midambles are based on bi-directional Partial Cyclic Shift Registers;

FIG. 5 shows the state of all the bi-directional Partial Cyclic Shift Registers of this invention after initial data sequence M are loaded;

FIG. 6 shows the mapping of outputting data of the present invention;

FIG. 7 shows the state of architecture of this invention after initial data are loaded;

FIG. 8 shows the state of architecture of this invention after one right shift operation is executed;

FIG. 9 shows the partial structure of a receiver containing the architecture of this invention;

FIG. 10 shows the partial structure of a transmitter containing the architecture of this invention.

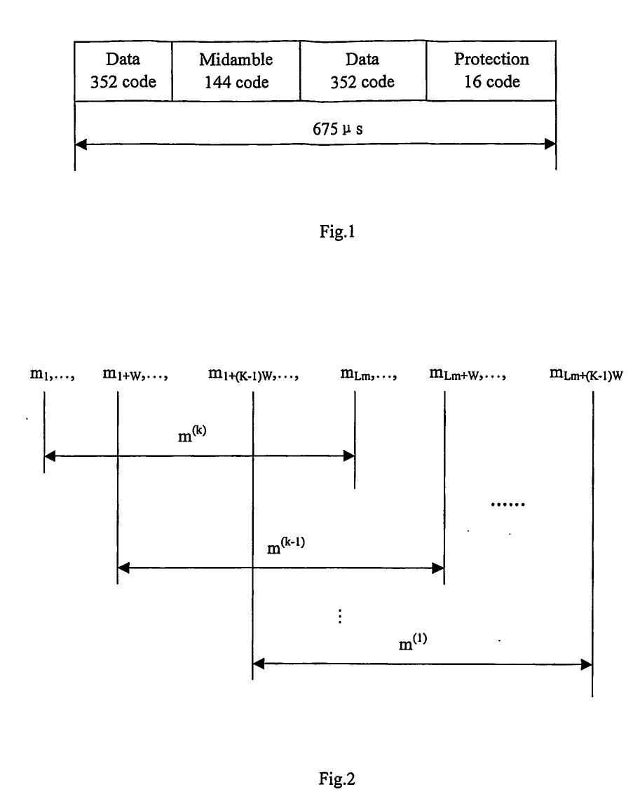

### DETAILED DESCRIPTION OF THE EMBODIMENT

Next, a further description of the present invention will be presented, accompanied by the attached Figures and implementation example.

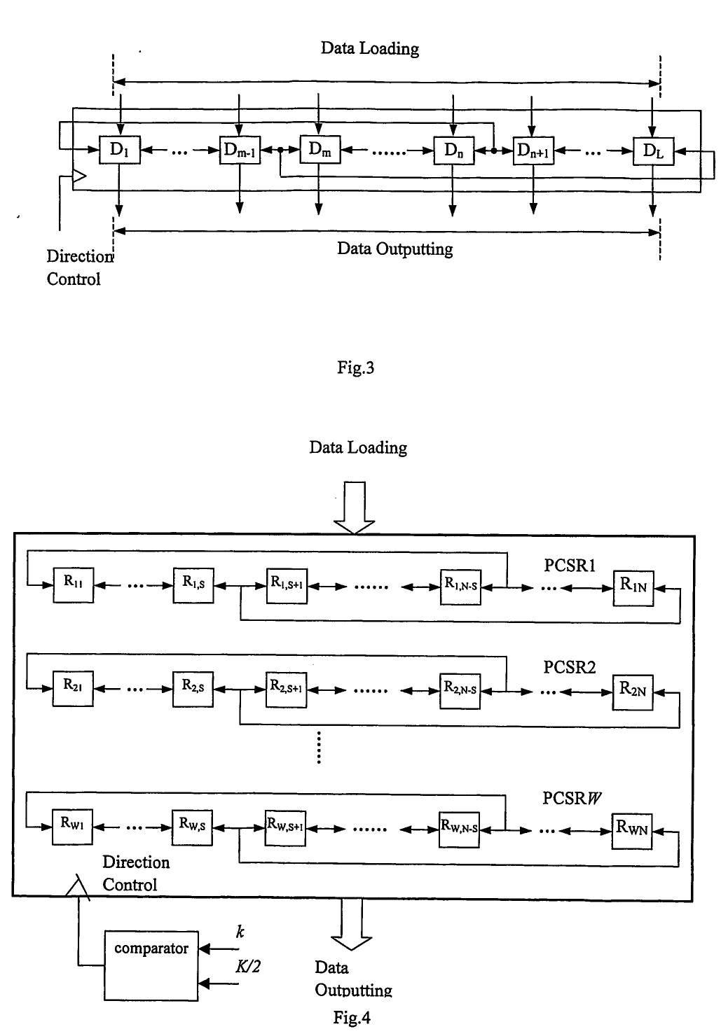

FIG. 3 shows the structure of bi-directional Partial Cyclic Shift Registers in this invention. As shown in FIG. 3, the bi-directional PCSR include a set of flip-flops serially connected from D₁ to D_{L} which can shift data bi-directionally, wherein L is positive integer greater than 1; two symmetrical partial feedback lines, one is feedback from intermediate data register Dₙ to D₁ to make up of a cycle, the other is feedback from intermediate data register Dₘ to D_{L} to make up of a cycle, wherein m<n (m, n are positive integers greater than 1 respectively); a set of data loading lines, which are used to load data into the said bi-directional PCSRs, and data output lines, which are used to output data from bi-directional PCSR, corresponding to flip-flops; and a direction control input.

The apparent difference between bi-directional PCSR and traditional CSR lies in direction control input and symmetrical partial feedback lines. The direction control input is used to select left/right shift working modes of the bi-directional partial cyclic shift registers. In FIG. 3, bi-directional arrows are used to represent left/right shift working modes of the bi-directional PCSRs. Apart from traditional CSR, bi-directional PCSR feeds back only the output of a special intermediate flip-flop to inner shift flip-flops, rather than to feed back data shifted out. For example, in FIG. 3, the output of intermediate flip-flops Dₘ and Dₙ should be fed back to D_{L} and D₁, i.e. only a part of sequence are in cyclic shift in bi-directional PCSRs, and the rest part will be finally shifted out after a defined shift degree. For example, in FIG. 3, if the direction control input selects left shift working mode, data from Dₘ to D_{L} are in cyclic shift, and data from D₁ to Dₘ₋₁ will be shifted out in turn after m−1 shift degree.

FIG. 4 shows the architecture of midamble generation in this invention based on bi-directional PCSRs. To avoid a too long register chain, the architecture this invention proposed uses a set of bi-directional PCSRs. As shown in FIG. 4, the whole architecture contains W identical PCSRs, and each PCSR contains N flip-flops; The direction control inputs of these bi-directional partial cyclic shift registers are connected together, and the left/right shift work modes of all these bi-directional partial cyclic shift registers are controlled by a uniform direction control input signal. The architecture also includes a comparator, the output of which is as the direction control input signal used to define the working modes of these said bi-directional partial cyclic shift registers. All these bi-directional partial cyclic shift registers work absolutely in parallel synchronously and there is no data exchanging or transmitting between each other.

In FIG. 4, subscripts of two dimension matrix are used to identify each flip-flop in all bi-directional PCSRs. For example, R_{MN} represents the Nth flip-flop in bi-directional PCSR M. As one bi-directional PCSR alone, initial data can be loaded into all the bi-directional PCSRs simultaneously through input bus, and data in all bi-directional PCSRs also can be outputted through output bus.

In FIG. 4, parameter W is defined by formula(3), and

$$N = \frac{{L}_{m}}{W} \qquad ( 7 )$$

$$S = \frac{{L}_{m} - p}{W} \qquad ( 8 )$$

In UTRAN TDD system, the method for midamble generation using architecture above includes the following steps:

First, extend periodically the whole basic midamble whose length is p, and load it into the W bi-directional PCSRs in architecture as the initial data. The architecture contains totally N×W=Lₘ flip-flops. The turn in which data are loaded is represented by the following formula:

$${R}_{ij} = \{ \begin{matrix}{\underline{m}}_{i + W \times ( j - 1 )} & 1 \leq i \leq W , j \leq \frac{p}{W} \\ {\underline{m}}_{i + W \times ( j - \frac{p}{W} - 1 )} & 1 \leq i \leq W , j > \frac{p}{W}\end{matrix} \qquad ( 9 )$$

wherein mⱼ, 1≦i≦p are the code elements of the basic midamble in formula(1).

FIG. 5 shows the state of all the bi-directional Partial Cyclic Shift Registers of this invention after initial data sequence M are loaded. After the sequence M whose length is s are loaded into the architecture above as the initial data, the state of all the bi-directional PCSRs is showed in FIG. 5. Seen from FIG. 5, the initial data are loaded into all the bi-directional PCSRs in architecture in turn in left-to-right column-prior sequence.

After the initial data are loaded, comparator compares the system required midamble number k to constant K/2. The result of comparison will influence directly the working mode of all the bi-directional PCSRs.

If k≧K/2 then all the bi-directional PCSRs work in left shift mode;

If k<K/2, then all the bi-directional PCSRs work in right shift mode.

The degree N_{S} of left/right shift can be obtained by the following formula:

$${N}_{S} = \{ \begin{matrix}K - k & k \geq \frac{K}{2} \\ k & k < \frac{K}{2}\end{matrix} \qquad ( 10 )$$

Apparently, to obtain any possible midamble, the bi-directional PCSRs in this architecture need at most K/2 degree left shift or K/2−1 degree right shift.

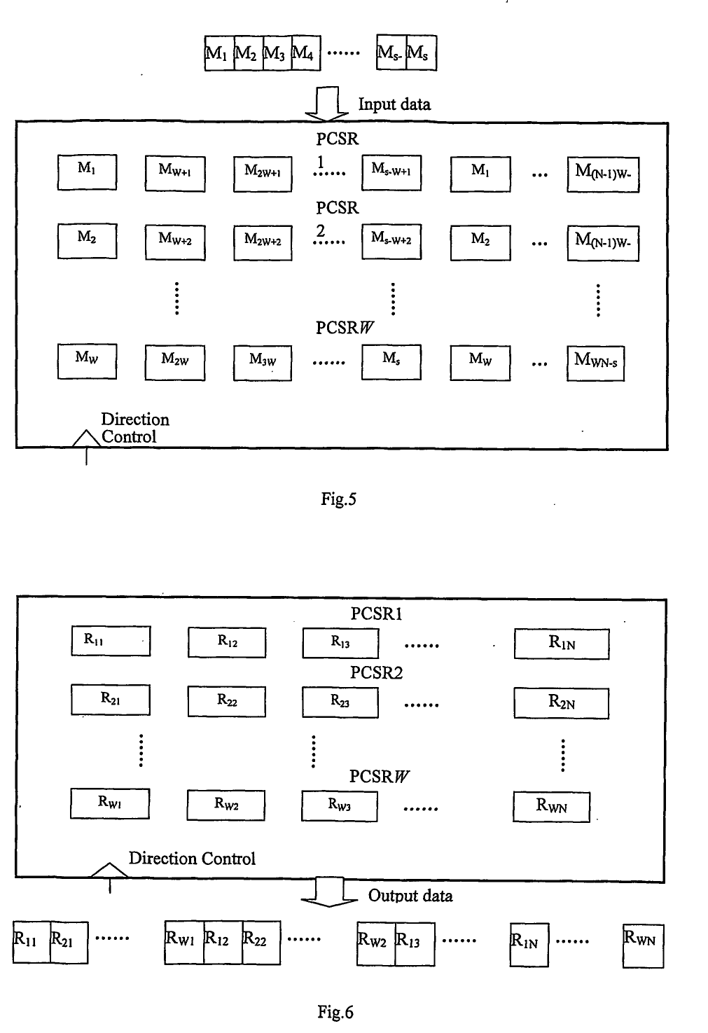

After the architecture above has finished the shift operation needed, all data in W bi-directional PCSRs should be downloaded as the final midamble. The turn in which data are downloaded is the same as initial data are loaded, i.e. in turn in left-to-right column-prior sequence. That means the data mapping can be expressed by the following formula:

$$\begin{matrix}{\underline{m}}_{i}^{( k )} = {R}_{i mod W , ⌈ \frac{i}{W} ⌉} & & i = 1 , 2 , ⋯ , {L}_{m} & & k = 1 , 2 , ⋯ , K\end{matrix} \qquad ( 11 )$$

Wherein mᵢ^{(k)} are the code elements of the final midamble defined in formula (5). When data in all the W bi-directional PCSRs are outputted as the final midamble, the data output mapping is showed in FIG. 6.

The following is an example of midamble m⁽¹⁾ generation using architecture in the present invention in UTRAN TDD low code ratio mode (1.28 Mcps mode).

In UTRAN TDD low code ratio mode, p=128. Lₘ=144, and we assume K=16. According to formula (3), we can conclude W= 128/16=8. So, eight bi-directional Partial Cyclic Shift Registers of the length of 18 should be totally used in the architecture. Since parameter S=(144−128)/8=2(see formula (8)), two symmetrical partial feedback lines start respectively from the corresponding second bit to cycle.

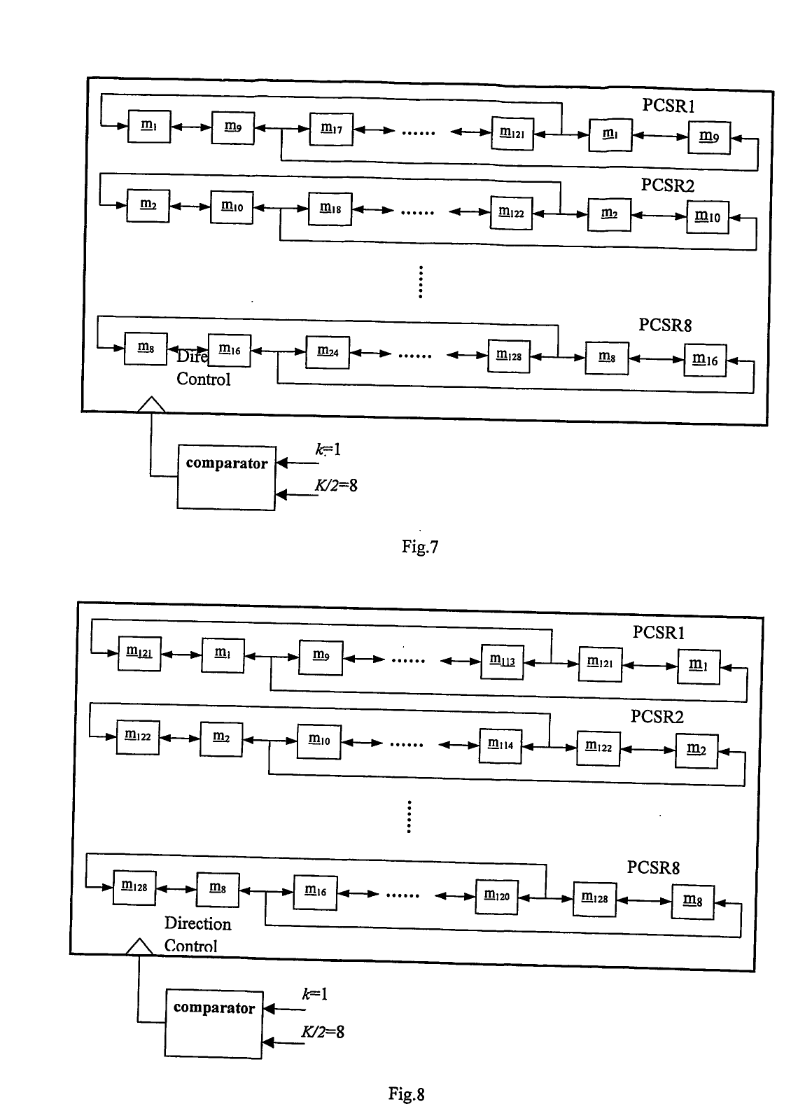

After the initial data are loaded, the state of the architecture is showed in FIG. 7, wherein mⱼ 1≦i≦128 are used to represent the code elements of the basic midamble defined in formula(1).

Comparator compares the needed midamble number k=1 to constant K/2=8. According to formula(10) and the determination rules mentioned above, the architecture needs to execute one right shift operation. FIG. 8 shows the state of architecture after all the bi-directional PCSRs have executed one right shift operation.

According to the data downloading turn defined in formula(11), we can get the output i.e. the final midamble m⁽¹⁾ are:
m₁₂₁ . . . m₁₂₈m₁m₂ . . . m₁₂₇m₁₂₈m₁ . . . m₈

The output code can also be obtained by formula (5) and (6), which is the same as m⁽¹⁾.

According to the architecuture for midamble generation of this invention, any final midamble can be generated within K/2 steps: In UTRAN TDD high or low code ratio modes, Kₘₐₓ=16, so, the longest waiting time is only eight clock cycles using the architecture of this invention for midamble generation.

Apart from the traditional architecture, the present invention's architecture provides users higher reuser ratio of sources and spares much gate resource. The traditional architecture must use at least 2×p latches to store periodically extended sequence. But this invention only needs Lₘ flip-flops, usually Lₘ is about a half of 2×p. For example, in UTRAN TDD low code ratio mode, 2×p=256 and Lₘ=144. The proposed architecture can spares nearly half gate resource.

The architecture of this invention for midamble generation can be used in receiver and transmitter in communication system or mobile terminal or base station.

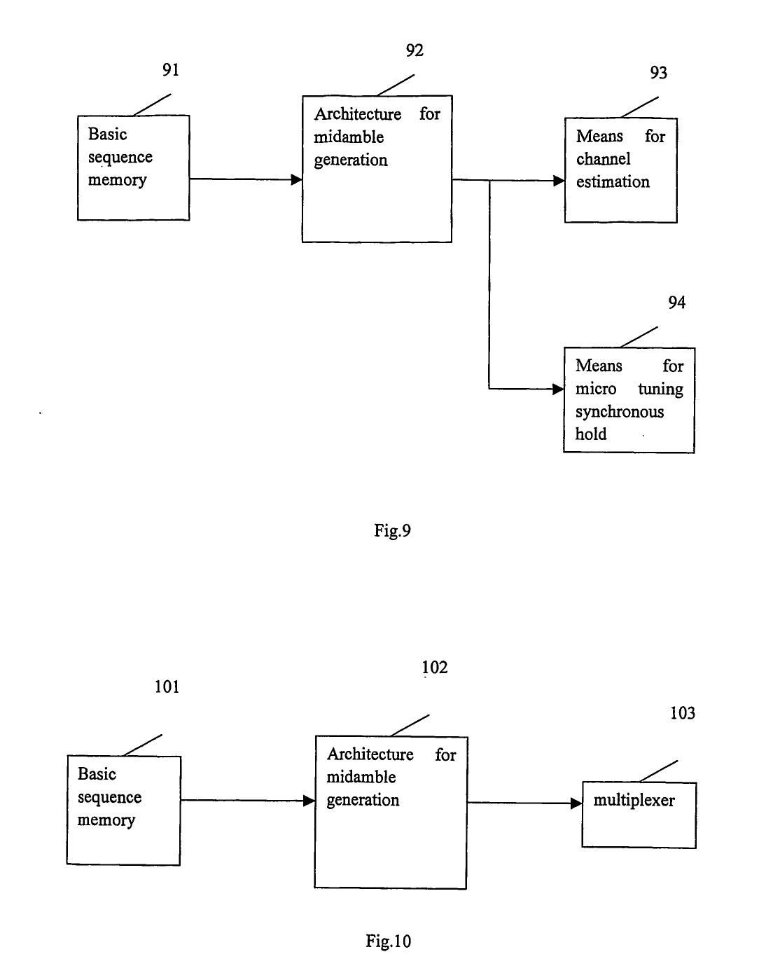

FIG. 9 shows the partial structure of a receiver containing the architecture of this invention. As shown in FIG. 9, the architecture 92 of midamble generation in the receiver gets the basic midamble sequence from the basic sequence memory in the receiver, and deals with the basic midamble sequence to get final midamble sequence, then transmit the final midamble sequence to means 93 for channel estimation and means 94 for micro tuning synchronous hold of the receiver. Other means of the receiver are of existing techniques, not shown in FIG. 9.

FIG. 10 shows the partial structure of a transmitter containing the architecture of this invention. As shown in FIG. 10, the architecture 102 of midamble generation in the transmitter gets the basic midamble sequence from the basic sequence memory 101 of the transmitter, and deals with the basic midamble sequence to get final midamble sequence, then transmit the final midamble sequence to multiplexer 103 in the transmitter. Other means of the transmitter are of existing techniques, not shown in FIG. 10.

What is claimed is:

1. A bi-directional partial cyclic shift register, including:
a set of data registers serially connected from D₁ to D_{L} which can shift data bi-directionally, wherein L is positive integer greater than 1;
two partial feedback lines, one is feedback from intermediate data register Dₙ to D₁ to make up of a cycle, the other is feedback from intermediate data register Dₘ to D_{L} to make up of a cycle; wherein m<n, and m, n are positive integer greater than 1 respectively;
and a direction control input, used to select left/right shift working modes of the bi-directional partial cyclic shift register.

2. As the bi-directional partial cyclic shift register of claim 1, wherein, when the work mode is selected, only a part of data are in the shift cycle, and rest part of the data will be finally shifted out after a certain number of cycles.

3. As the bi-directional partial cyclic shift register of claim 1, wherein two partial feedback lines are symmetric.

4. An architecture for midamble generation in communication system, including:
a set of identical parallel bi-directional partial cyclic shift registers of claim 1, wherein two dimensional matrix are used to identify each data register of bi-directional partial cyclic shift registers, each bi-directional partial cyclic shift register has the same length, and the sum length of all the bi-directional partial cyclic shift registers is equal to the length of final midamble sequence.

5. As the architecture of claim 4, wherein the said architecture totally includes N×W=Lₘ data registers, of which N represents the number of the data register in each bi-directional partial cyclic shift register of the architecture, and W represents the number of the bi-directional partial cyclic shift register in the architecture.

6. As the architecture of claim 4, wherein the direction control inputs of these said bi-directional partial cyclic shift registers are connected, and the left/right shift work modes of all these bi-directional partial cyclic shift registers are controlled by a uniform direction control input signal.

7. As the architecture of claim 6, wherein the said architecture also includes a comparator, the output of which is as the direction control input signal used to define the working modes of these said bi-directional partial cyclic shift registers.

8. As the architecture of claim 4, wherein these said bi-directional partial cyclic shift registers work absolutely in parallel synchronously and there is no data exchanging or transmitting between each other.

9. In communication systems, a method of midamble generation with the architecture of claim 4, including:
a. the whole basic midamble sequences are periodically extended and are loaded into the bi-directional partial cyclic shift registers of the architecture of claim 4;
b. when step a is accomplished, the comparator compares the number of the system required midamble k with a constant K/2, and determine the shift direction of all the bi-directional partial cyclic shift registers, wherein K greater than or equal to k, and K, k are positive integer greater than or equal to 1;
c. then the shift degrees of all the bi-directional partial cyclic shift registers are determined by the shift direction of the bi-directional partial cyclic shift register, the number of the midamble k and a constant K;
d. according to the determined shift direction and shift degrees, all these bi-directional partial cyclic shift registers perform shifting operations;
e. when the said architecture has finished the demanded shifting operations, all the data in these bi-directional partial cyclic shift registers are loaded as final midamble sequence.

10. As the method of claim 9, wherein the extended basic midamble sequences in said step a are loaded into the bi-directional partial cyclic shift register in the architecture of claim 4 in turn in left-to-right column-prior sequence.

11. As the method of claim 9, wherein all bi-directional partial cyclic shift registers work in right shift mode when the number of the midamble k is less than the initial constant K/2 in the said step b, otherwise, all bi-directional partial cyclic shift registers work in left shift mode.

12. As the method of claim 9, wherein the shift degree is K-k when bi-directional partial cyclic shift register works in right shift mode in the said step c, otherwise, the shift number is k.

13. As the method of claim 9, wherein the bi-directional partial cyclic shift registers perform shift operations in same direction and same degrees in the said step d.

14. As the method of claim 9, wherein all the bi-directional partial cyclic shift registers are downloaded as final midamble sequence in turn in left-to-right column-prior sequence in the said step e.

15. A communication system, including receiver and transmitter, both of which contain the architecture of midamble generation of claim 4.

16. As the communication system of claim 15, wherein the architecture of midamble generation in the receiver gets the basic midamble sequence from the basic sequence memory in the receiver, and deals with the basic midamble sequence to get final midamble sequence, then transmit the final midamble sequence to means for channel estimation and means for micro tuning synchronous hold of the receiver.

17. As the communication system of claim 15, wherein the architecture of midamble generation in the transmitter gets the basic midamble sequence from the basic sequence memory of the transmitter, and deals with the basic midamble sequence to get final midamble sequence, then transmit the final midamble sequence to multiplexer in the transmitter.

18. A mobile terminal, including receiver and transmitter, both of which contain the architecture of midamble generation of claim 4.

19. As the mobile terminal of claim 18, wherein the architecture of midamble generation in the receiver gets the basic midamble sequence from the basic sequence memory in the receiver, and deals with the basic midamble sequence to get final midamble sequence, then transmit the final midamble sequence to means for channel estimation and means for micro tuning synchronous hold of the receiver.

20. As the mobile terminal of claim 19, wherein the architecture of midamble generation in the transmitter gets the basic midamble sequence from the basic sequence memory of the transmitter, and deals with the basic midamble sequence to get final midamble sequence, then transmit the final midamble sequence to multiplexer in the transmitter.
